(19) United States
(12) Patent Application Publication
(10) Pub. No.: US 2012/0326747 A1
(43) Pub. Date: Dec. 27, 2012

(54) RECONFIGURABLE LOGIC DEVICE

(75) Inventors: Hyun-su Jeong, Suwon-si (KR); Ho-jung Kim, Suwon-si (KR); Jai-kwang Shin, Anyang-si (KR); Hyun-sik Choi, Hwaseong-si (KR)

(73) Assignee: SAMSUNG ELECTRONICS CO., LTD., Suwon-si (KR)

(21) Appl. No.: 13/449,778

(22) Filed: Apr. 18, 2012

(30) Foreign Application Priority Data
Jun. 27, 2011 (KR) 10-2011-0062481

(51) Int. Cl. H03K 19/173

(52) U.S. Cl. 326/38

(57) ABSTRACT

A logic device that includes a plurality of non-volatile memory cells configured to store possible output results related to the input signal. The logic device generating an output signal by selecting and accessing one of the plurality of non-volatile memory cells based on the input signal.

### CROSS-REFERENCE TO RELATED APPLICATIONS

This application claims the benefit of Korean Patent Application No. 10-2011-0062481, filed on Jun. 27, 2011, in the Korean Intellectual Property Office, the disclosure of which is incorporated herein in its entirety by reference.

### BACKGROUND

1. Field

One or more example embodiments relate to reconfigurable logic devices and/or semiconductor packages including the same.

2. Description of the Related Art

Recently, use of reconfigurable logic devices, e.g., a programmable logic device (PLD) that can be easily and arbitrarily designed by a user, has become widespread. A user may reconfigure a logic device to perform a desired operation by controlling routing between interconnection lines included in the logic device.

### SUMMARY

Provided are reconfigurable logic devices that are more efficiently structured and are capable of operating at relatively high speeds.

Additional aspects will be set forth in part in the description which follows and, in part, will be apparent from the description, or may be learned by practice of the example embodiments.

According to one or more example embodiments, a logic device includes a plurality of non-volatile memory cells configured to store possible output results related to an input signal, wherein the logic device generates an output signal by selecting and accessing one of the plurality of non-volatile memory cells based on the input signal.

The logic device may be structured to be reconfigured by selecting one of the plurality of non-volatile memory cells based on the input signal and storing information for performing the operation in the selected non-volatile memory cell.

The logic device may further include a decoder configured to generate a word line signal and a bit line signal based on the input signal, and wherein the plurality of non-volatile memory cells may be accessed based on the word line signal and the bit line signal.

The logic device may further include at least one common source line connected to source terminals of the plurality of non-volatile memory cells.

Each of the plurality of non-volatile memory cells may include a resistive memory device; and a transistor including a gate that receives the word line signal, a drain that receives the bit line signal, and a source connected to the resistive memory device.

The resistive memory device may be connected between the source of the transistor and a corresponding source terminal.

The logic device may further include a plurality of word lines for transmitting the word line signal to the gate of the transistor, the plurality of word lines extending in a first direction; and a plurality of bit lines for transmitting the bit line signal to the drain of the transistor, the plurality of bit lines extending in a second direction that is substantially perpendicular to the first direction.

The non-volatile memory cells may be arranged in an array, in the first and second directions.

The logic device may further include a plurality of separated source lines connected between the plurality of non-volatile memory cells and a decoder. Each of the plurality of separated source lines may be connected to source terminals of non-volatile memory cells arranged in the second direction from among the plurality of non-volatile memory cells.

The decoder may generate a source line signal based on the input signal, and the source line signal may be transmitted to the source terminals via the plurality of separated source lines.

According to another example embodiment, a logic device includes a plurality of non-volatile memory cells configured to store all possible output results related to an input signal; a plurality of word lines configured to transmit a word line signal to the plurality of non-volatile memory cells; and a plurality of bit lines configured to transmit a bit line signal to the plurality of non-volatile memory cells, wherein the logic device generates an output signal by selecting and accessing one of the plurality of non-volatile memory cells based on the word line signal and the bit line signal.

The non-volatile memory cells may be arranged in an array.

The logic device may further include common source lines connected to source terminals of the plurality of non-volatile memory cells.

The logic device may further include a decoder configured to generate the word line signal and the bit line signal based on the input signal.

The logic device may further include a plurality of separated source lines connected between the plurality of non-volatile memory cells and the decoder. The plurality of separated source lines may be respectively connected to source terminals of non-volatile memory cells disposed in a direction in which the plurality of bit lines extend, from among the plurality of non-volatile memory cells.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic block diagram of an electronic circuit module including a conventional logic device and an external memory device;

FIG. 2 is a schematic block diagram of an electronic circuit module including a logic device according to an example embodiment;

FIG. 3 is a schematic block diagram of a functional block included in a logic device, according to an example embodiment;

FIG. 4 is a schematic block diagram of a functional block included in a logic device, according to another example embodiment;

FIG. 5 is a timing diagram of signals used when the logic device of FIG. 3 performs a read operation, according to an example embodiment;

FIG. 6 is an enlarged view of a part A of the timing diagram of FIG. 5; and

FIG. 7 is a schematic block diagram of a functional block included in a logic device, according to another example embodiment.

### DETAILED DESCRIPTION

Reference will now be made in detail to example embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects of the present description.

The present invention may, however, be embodied in many different forms and should not be construed as being limited to the example embodiments set forth herein. Rather, these embodiments are provided so that this disclosure will be thorough and complete and will fully convey the concept of the invention to those of ordinary skill in the art.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

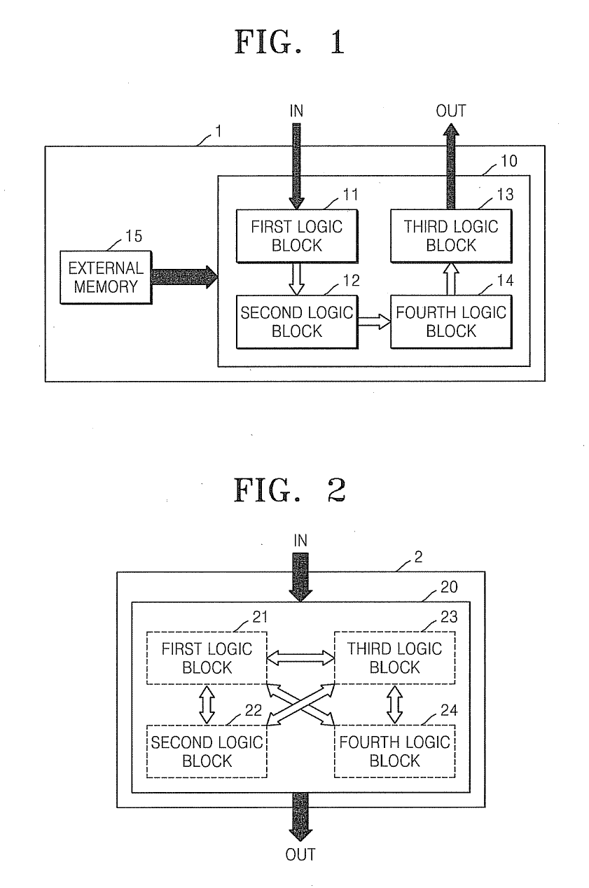

FIG. 1 is a schematic block diagram of an electronic circuit module 1 including a logic device 10 and an external memory device 15.

Referring to FIG. 1, the electronic circuit module 1 may include the logic device 10 having a plurality of logic blocks 11, 12, 13, and 14, and the external memory device 15. The logic device 10 is a programmable logic device (PLD), e.g., a field programmable gate array (FPGA), a programmable array logic (PAL), a programmable logic array (PLA), or a generic array logic (GAL). The external memory device 15 stores connection information regarding interconnections lines between the plurality of logic blocks 11 to 14 included in the logic device 10. The external memory device 15 may be, for example, flash memory or read-only memory (ROM).

When power is supplied to the electronic circuit module 1, the connection information stored in the external memory device 15 is loaded into the logic device 10. The plurality of logic blocks 11 to 14 are connected to one another based on the connection information. An operation of the logic device 10 is defined according to a connection between the plurality of logic blocks 11 to 14. Thus, in order to define an operation of the logic device 10, the connection information regarding the interconnection lines between the plurality of logic blocks 11 to 14 should be programmed, the programmed connection information should be stored in the external memory device 15, and the stored connection information should be loaded into the logic device 10. Thus, it is relatively difficult to reconfigure the logic device 10 in real time. Further, the conventional logic device 10 includes the external memory device 15, which increases the size of the electronic circuit module 1 and manufacturing costs thereof.

FIG. 2 is a schematic block diagram of an electronic circuit module 2 including a logic device 20 according to a example embodiment of the present invention.

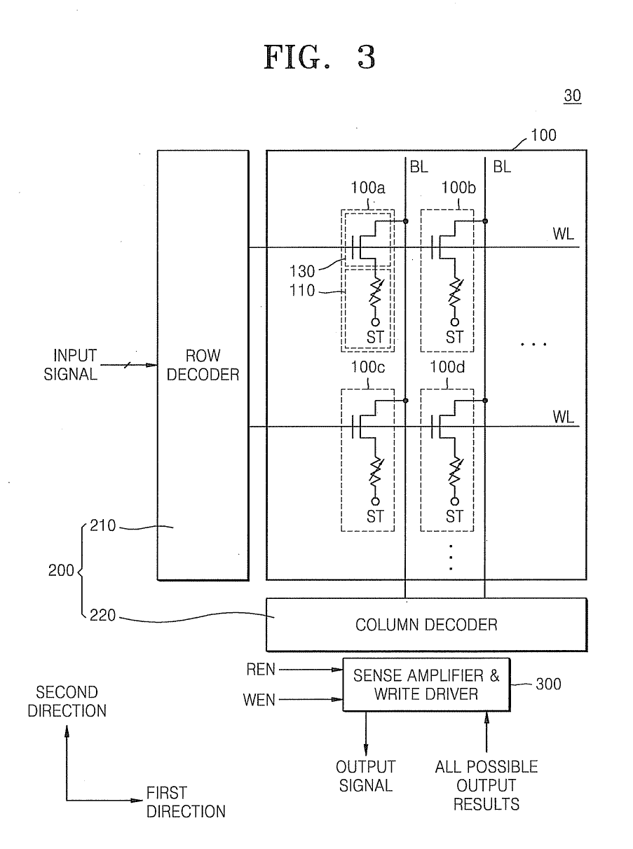

Referring to FIG. 2, the electronic circuit module 2 may include the logic device 20 having a plurality of logic blocks 21, 22, 23, and 24. The plurality of logic blocks 21 to 24 may be interconnected by interconnection lines located between the plurality of logic blocks 21 to 24. In the current embodiment, the logic device 20 may include a plurality of non-volatile memory devices such as shown in FIG. 3. Routing may be controlled between the plurality of logic blocks 21 to 24 or between the functional blocks included in each of the plurality of logic blocks 21 to 24 by writing, programming, data regarding the plurality of non-volatile memory devices. For example, interconnection information, connection information, routing information, etc. may be programmed in the plurality non-volatile of memory devices.

As described above, since the logic device 20 includes the plurality of non-volatile memory devices, the electronic circuit module 2 does not need to additionally include an external memory device. Thus, in order to redefine an operation of the logic device 20, i.e., in order to reconfigure the operation of the logic device 20, the connection information regarding the interconnection lines between the plurality of logic blocks 21 to 24 and/or between the plurality of functional blocks included in each of the plurality of logic blocks 21 to 24 may be programmed in the plurality of non-volatile memory devices in real time and the plurality of logic blocks 21 to 24 and/or the functional blocks included in each of the plurality of logic blocks 21 to 24 may be connected to one another based on the programmed connection information. Accordingly, the logic device 20 may be easily reconfigured in real time, and need not include an external memory device, thereby reducing the size of the electronic circuit module 2.

FIG. 3 is a schematic block diagram of a functional block 30 included in a logic device (not shown), according to an example embodiment. The logic device may include a plurality of logic blocks, each of which may have a plurality of functional blocks 30. Here, the functional block 30 may be defined as a block that may be transformed from one data format to another data format.

More specifically, the functional block 30 may include a plurality of non-volatile memory cells 100, and may store all possible output results related to an input signal in the plurality of non-volatile memory cells 100 in the form of a table. The functional block 30 may perform an operation based on such information stored in the form of a table. For example, the functional block 30 may receive an input signal and access and output the information stored in the form of a table according to the input signal. The functional block 30 may be embodied as an Intellectual Property (IP) block or a Look-Up Table (LUT) block. In the example embodiment discussed, it is assumed in FIG. 3 that the functional block 30 is a LUT block.

Referring to FIG. 3, the functional block 30 may output an output signal related to an input signal so as to perform a desired operation. The output signal corresponds to the information stored in the form of a table, which includes output results obtained by performing various operations.

The functional block 30 in the logic device may store all possible output results related to an input signal. The possible output results may be stored in the form of a table.

For example, if the logic device is set to perform an operation, for example a 2-bit XOR operation, then the plurality of non-volatile memory cells 100 may be programmed to produce output results as shown in the following Table 1 (a truth table) below. In Table 1, it is assumed that an input signal is a 2-bit input signal <0:1>.

TABLE 1

| Input | Input | | |
|---|---|---|---|
| signal <0> | signal <1> | Output result | Storage location |
| 0 | 0 | 0 | First non-volatile memory cell |
| | | | 100a |
| 0 | 1 | 1 | Second non-volatile memory cell |
| | | | 100b |
| 1 | 0 | 1 | Third non-volatile memory cell |
| | | | 100c |
| 1 | 1 | 0 | Fourth non-volatile memory cell |
| | | | 100d |

In other words, first to fourth non-volatile memory cells 100 may be programmed as shown in Table 1. One of the first to fourth non-volatile memory cells 100 is selected based on an input signal, and the information for performing the desired operation, i.e., the output results, is stored in the selected non-volatile memory cell 100.

After the programming, one of the non-volatile memory cells 100 may be selected based on an input signal, i.e., a 2-bit input signal <0:1>, and an output signal may be produced by accessing the information stored in the selected non-volatile memory cell 100. Thus, the logic device may perform the desired operation, e.g., the 2-bit XOR operation.

Accordingly, the logic device may be reconfigured by programming the possible output results related to an input signal in the plurality of non-volatile memory cells 100. The reconfigured logic device may perform a desired operation by accessing, e.g., by reading such information from, the plurality of non-volatile memory cells 100 therein.

Such write and read operations are performed based on an input signal. The write and read operations are performed by selecting a desired non-volatile memory cell from among the plurality of non-volatile memory cells 100. Thus, the logic device may further include a decoder unit 200 that generates signals for selecting one of the plurality of non-volatile memory cells 100 based on an input signal.

For example, signals for selecting one of the plurality of non-volatile memory cells 100 may include a word line signal and a bit line signal. The decoder unit 200 may generate a word line signal and a bit line signal based on an input signal, and the plurality of non-volatile memory cells 100 may be accessed based on the word line signal and the bit line signal.

Each of the non-volatile memory cells 100 may include a resistive memory device 110 and a switching device 130.

The resistive memory device 110 may include an oxide insulator. A resistance value of the oxide insulator may be changed by supplying an electric current to the oxide insulator. In one or more example embodiments, at least one of the plurality of non-volatile memory cells 100 uses the resistive memory device 110.

A logic device according to one or more example embodiments employs the resistive memory device 110, which includes a plurality of non-volatile memory cells 100. By utilizing the plurality of non-volatile memory cells 100, the example embodiments reduce power consumption, operate the logic device at high speeds, and efficiently structure the circuit, thereby reducing the chip size.

The switching device 130 may be embodied as, for example, a transistor. The transistor may include a gate that receives a word line signal generated by the decoder unit 200, e.g., the row decoder 210, a drain that receives a bit line signal generated by the decoder unit 200, e.g., the column decoder 220, and a source connected to the resistive memory device 110.

The resistive memory device 110 may be connected between a source terminal ST and the source of the transistor of each of the resistive memory devices 110. In this case, the plurality of non-volatile memory cells 100, and particularly, the source terminals ST of the resistive memory devices 110 may be electrically connected to one another, thereby forming a common source line.

For example, during the write and read operations, the source terminals ST may be connected to a ground voltage terminal (not shown). Accordingly, a voltage may be applied to only a non-volatile memory cell 100 selected based on an input signal, and data may be written to or read from the selected non-volatile memory cell 100.

During an erase operation in which data is erased from the plurality of non-volatile memory cells 100, the source terminals ST may be connected to a high-voltage terminal for performing the erase operation. When a high voltage is applied to the source terminals ST from the high-voltage terminal, all of data stored in the plurality of non-volatile memory cells 100 may be erased. In other words, the data stored in the plurality of non-volatile memory cells 100 may be simultaneously erased by applying a high voltage to the source terminals ST.

In an example embodiment, since the logic device uses the source terminals ST, a source line may be shared, and thus, a layout for configuring a source line is not needed. Thus, a structure of a circuit, e.g., the decoder unit 200, may be simplified and a chip size may be reduced.

A plurality of the resistive memory devices 110 may be disposed in an array. More specifically, the logic device may include a plurality of word lines WL connected to a row decoder 210 and a plurality of bit lines BL connected to a column decoder 220. The plurality of non-volatile memory cells 100 may be disposed to correspond to intersections of the plurality of word lines WL and the plurality of bit lines BL. The gate of the transistor of each of the plurality of non-volatile memory cells 100 is connected to a corresponding word line WL to receive a word line signal, and the drain of the transistor of each of the plurality of non-volatile memory cells 100 is connected to a corresponding bit line BL to receive a bit line signal.

The plurality of word lines WL may extend in a first direction, and the plurality of bit lines BL may extend in a second direction that is substantially perpendicular to the first direction. Thus, the plurality of non-volatile memory cells 100 disposed to correspond to the intersections of the plurality of word lines WL and the plurality of bit lines BL, may be arranged in an array, in the first and second directions.

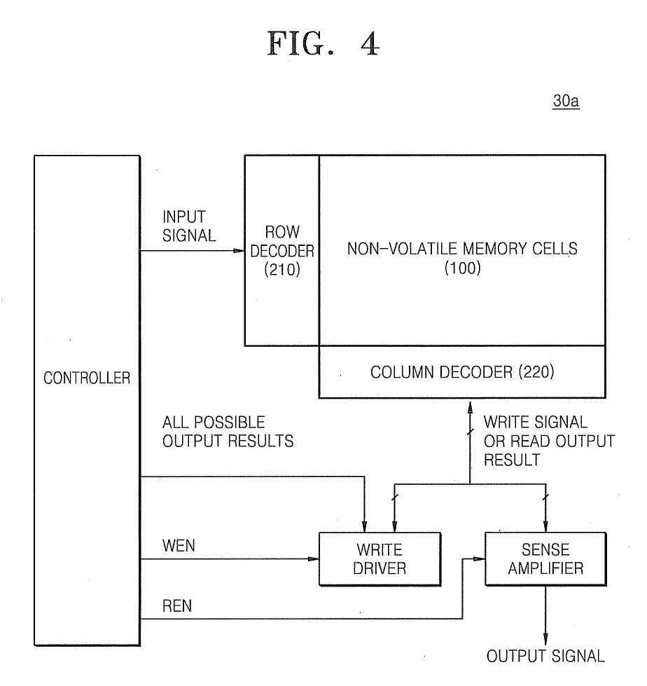

FIG. 4 is a schematic block diagram of a functional block 30a included in a logic device, according to an example embodiment. The logic device 30a may be a modified example of the logic device 30 of FIG. 3. A description of the parts of functional block 30a that are the same as that of the functional block 30 of FIG. 3 will not be repeated for the sake of brevity.

Referring to FIG. 4, during a write operation, the functional block 30a in the logic device may program output results corresponding to a truth table for performing an operation, in a plurality of non-volatile memory cells 100. To this end, a write driver is activated according to a write enable signal. The write driver may transmit a write signal to a column decoder 220, based on all possible output results.

A row decoder 210 generates a word line signal based on an input signal, and the column decoder 220 generates a bit line signal based on the input signal and the write signal (a signal generated based on the all possible output results) received from the write driver. In this case, common source lines of the plurality of non-volatile memory cells 100 are electrically connected to one another, and particularly, to a ground voltage terminal (not shown). One of the plurality of non-volatile memory cells 100 may be selected based on the word line signal and the bit line signal, and an output result may be stored in the selected non-volatile memory cell 100.

During an erase operation, the common source lines of the plurality of non-volatile memory cells 100 may be connected to a high-voltage terminal for performing the erase operation. When a high voltage is applied to the common source lines from the high-voltage terminal, data may be completely erased from the plurality of non-volatile memory cells 100. In this way, information for performing an operation, i.e., all possible output results, may be stored in or erased from the plurality of non-volatile memory cells 100.

During a read operation, the logic device may select desired one from among the plurality of non-volatile memory devices 100, based on the word line signal and the bit line signal, and perform an operation by accessing an output result stored in the selected non-volatile memory cell 100. To this end, a sense amplifier is activated according to a read enable signal. The sense amplifier may generate an output signal by amplifying a result of the accessing.

More specifically, the row decoder 210 generates a word line signal and the column decoder 220 generates a bit line signal, based on an input signal. In this case, the common source lines of the plurality of non-volatile memory cells 100 may be electrically connected to one another, and particularly, to the ground voltage terminal. One of the plurality of non-volatile memory cells 100 may be selected and accessed based on the word line signal and the bit line signal, and an output result stored in the selected non-volatile memory cell may be read. A result of the reading is transmitted to the sense amplifier, and the sense amplifier outputs an output signal by amplifying the result of the reading.

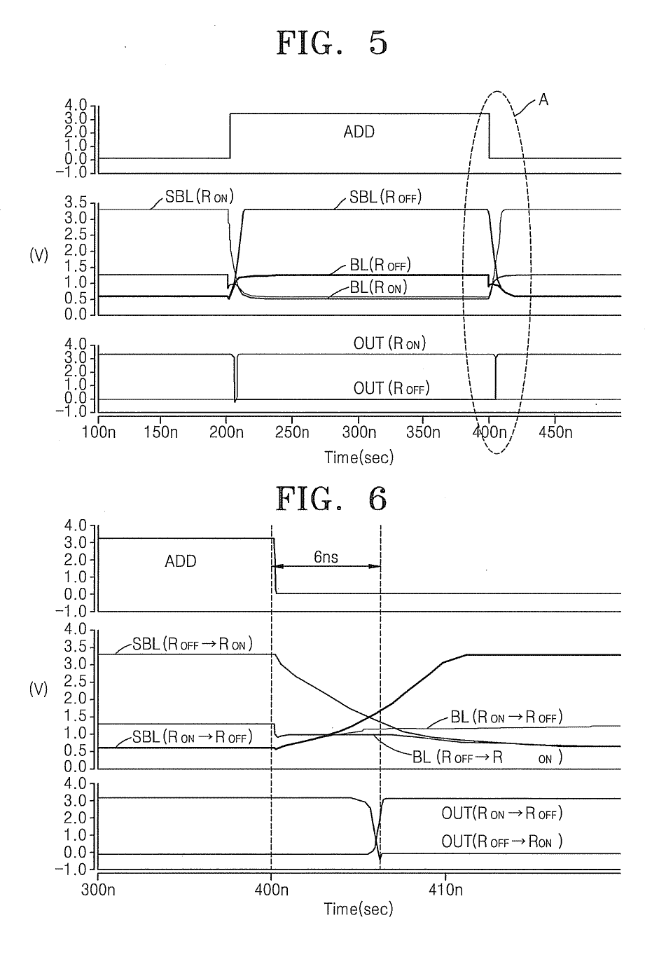

FIG. 5 is a timing diagram of signals used when the logic device of FIG. 3 performs a read operation, according to an example embodiment. FIG. 6 is an enlarged view of a part A of the timing diagram of FIG. 5. Referring to FIGS. 3 and 5, an address signal ADD goes from logic low to logic high at about 200 ns (from looking at timing diagram it would be more accurate to say “at about 210 ns” or even “at about 208 ns”). The address signal ADD is fed as an input signal to the row decoder (210). A word line signal and a bit line signal are generated based on a logic level transition of the address signal ADD. One of the plurality of non-volatile memory cells 100 is selected and accessed based on the word line signal and the bit line signal.

If the accessed non-volatile memory cell 100 is ‘off’, then the accessed non-volatile memory cell 100 may have an ‘off’ resistance value R_{OFF}. In this case, a bit line signal BL(R_{OFF}) output from a bit line connected to the accessed non-volatile memory cell 100 may be logic high. A sense amplifier amplifies the bit line signal BL(R_{OFF}) and outputs an amplified bit line signal SBL(R_{OFF}). Then, a high-level output signal OUT(R_{OFF}) may be output based on a logic level of the amplified bit line signal SBL(R_{OFF}).

If the accessed non-volatile memory cell 100 is ‘on’, then the accessed non-volatile memory cell 100 may have an ‘on’ resistance value R_{ON}. In this case, a bit line signal BL(R_{ON}) output from the bit line BL connected to the non-volatile memory cell 100 may be logic low. The sense amplifier amplifies the bit line signal BL(R_{ON}) and outputs the amplified bit line signal SBL(R_{ON}). Then, a low-level output signal OUT(R_{ON}) may be output based on a logic level of the amplified bit line signal SBL(R_{ON}).

The above operation at about 200 ns may be performed again at about 400 ns. Referring to FIGS. 3 and 6, an address signal ADD goes from logic high to logic low. The address signal ADD is fed as an input signal to the row decoder (100). Thus, a word line signal and a bit line signal are generated based on such a logic level transition of the address signal ADD, and one of the plurality of non-volatile memory cells 100 is selected and accessed based on the word line signal and the bit line signal.

If a non-volatile memory cell 100 accessed at about 200 ns is ‘on’ and a non-volatile memory cell 100 accessed at about 400 ns is ‘off’, then a bit line signal BL(R_{ON}->R_{OFF}) from the bit line BL connected to the selected non-volatile memory cell goes from low to high. The sense amplifier amplifies the bit line signal BL(R_{ON}->R_{OFF}) and outputs the amplified bit line signal SBL(R_{ON}->R_{OFF}). Then, a high-level output signal OUT(R_{ON}->R_{OFF}) may be output based on a logic level of the amplified bit line signal SBL(R_{ON}->R_{OFF}).

If the non-volatile memory cell 100 accessed at about 200 ns is ‘off’ and the non-volatile memory cell 100 accessed at about 400 ns is ‘on’, then a bit line signal BL(R_{OFF}->R_{ON}) the bit line BL connected to the selected non-volatile memory cell goes from high to low. The sense amplifier amplifies the bit line signal BL(R_{OFF}->R_{ON}) and outputs the amplified bit line signal SBL(R_{OFF}->R_{ON}). Then, a low-level output signal OUT(R_{OFF}->R_{ON}) may be output based on a logic level of the bit line signal SBL(R_{OFF}->R_{ON}).

As illustrated in FIG. 6, a logic device according to an example embodiment may perform a read operation, based on a logic level transition of an address signal ADD in a time period of only about 6 ns. That is, an operating speed of a logic device according to an example embodiment increases. Furthermore, a chip size and the decoder unit 200 of FIG. 3 may be optimized using an array of memory cells. Also, the number of non-volatile memory cells may be increased, as the address signal ADD is used to access the non-volatile memory cells. Thus, a high-bit logic device as described in the example embodiments may be manufactured more efficiently.

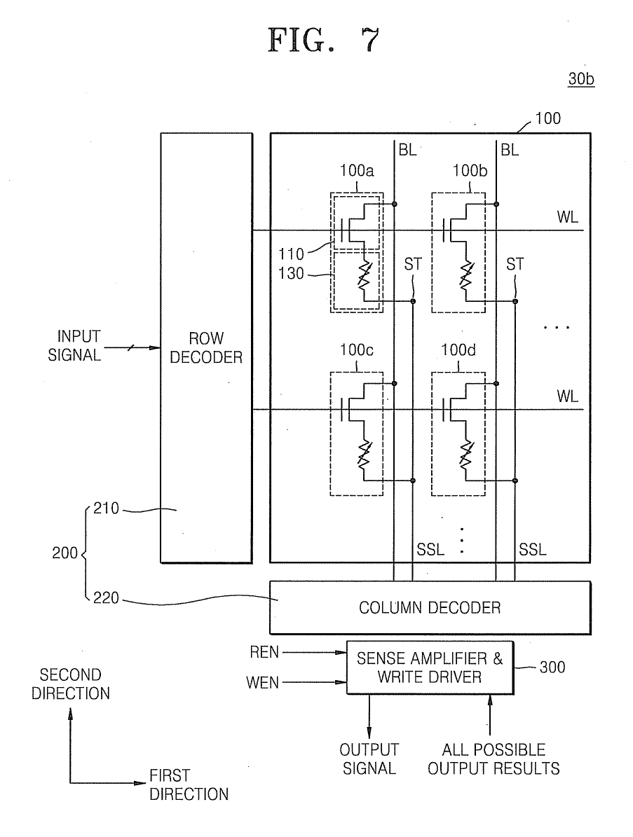

FIG. 7 is a schematic block diagram of a functional block 30b included in a logic device, according to another example embodiment. The logic device 30b may be a modified example of the logic device 30 of FIG. 3. A description of the functional block 30b that is the same as that of the functional block 30 of FIG. 3 will not be repeated.

Referring to FIG. 7, the functional block 30b in the logic device may further include separated source lines SSL, in contrast to the functional block 30 of FIG. 3. The plurality of separated source lines SSL may be connected between a plurality of non-volatile memory cells 100 and a decoder unit 200. More specifically, each of the plurality of separated source lines SSL may be connected to source terminals ST of non-volatile memory cells 100 disposed in a direction in which a plurality of bit lines BL extend, i.e., in a second direction, from among the plurality of non-volatile memory cells 100.

In this case, the decoder unit 200, and particularly, a column decoder 220 may further generate a source line signal based on an input signal. The plurality of separated source lines SSL may transmit the source line signal to the source terminals ST of specific non-volatile memory cells 100. Compared to the embodiment of FIG. 3 using common source lines, in the example embodiment of FIG. 7, separated source lines (SSL) are used, and thus the plurality of non-volatile memory cells 100 may be individually erased during an erase operation. Accordingly, the plurality of non-volatile memory cells 100 may be individually controlled.

It should be understood that the example embodiments described herein should be considered in a descriptive sense only and not for purposes of limitation. Descriptions of features or aspects within each embodiment should typically be considered as available for other similar features or aspects in other example embodiments.

What is claimed is:

1. A logic device, comprising:
a plurality of non-volatile memory cells configured to store possible output results related to an input signal; and wherein the logic device generates an output signal by selecting and accessing one of the plurality of non-volatile memory cells based on the input signal.

2. The logic device of claim 1, wherein the logic device is structured to be reconfigured by selecting one of the plurality of non-volatile memory cells based on the input signal and storing information for performing the operation in the selected non-volatile memory cell.

3. The logic device of claim 1, further comprising:
a decoder configured to generate a word line signal and a bit line signal based on the input signal, and
wherein the plurality of non-volatile memory cells are accessed based on the word line signal and the bit line signal.

4. The logic device of claim 1, further comprising:
at least one common source line connected to source terminals of the plurality of non-volatile memory cells.

5. The logic device of claim 1, wherein each of the plurality of non-volatile memory cells comprises:
a resistive memory device; and
a transistor including a gate that receives the word line signal, a drain that receives the bit line signal, and a source connected to the resistive memory device.

6. The logic device of claim 5, wherein the resistive memory device is connected between the source of the transistor and a corresponding source terminal.

7. The logic device of claim 5, further comprising:
a plurality of word lines for transmitting the word line signal to the gate of the transistor, the plurality of word lines extending in a first direction; and
a plurality of bit lines for transmitting the bit line signal to the drain of the transistor, the plurality of bit lines extending in a second direction that is substantially perpendicular to the first direction.

8. The logic device of claim 7, wherein the non-volatile memory cells are arranged in an array, in the first and second directions.

9. The logic device of claim 1, further comprising:
a plurality of separated source lines connected between the plurality of non-volatile memory cells and a decoder,
wherein each of the plurality of separated source lines are connected to source terminals of non-volatile memory cells arranged in the second direction from among the plurality of non-volatile memory cells.

10. The logic device of claim 9, wherein,
the decoder generates a source line signal based on the input signal, and
the source line signal is transmitted to the source terminals via the plurality of separated source lines.

11. A logic device, comprising:
a plurality of non-volatile memory cells configured to store possible output results related to an input signal;
a plurality of word lines configured to transmit a word line signal to the plurality of non-volatile memory cells; and
a plurality of bit lines configured to transmit a bit line signal to the plurality of non-volatile memory cells,
wherein the logic device generates an output signal by selecting and accessing one of the plurality of non-volatile memory cells based on the word line signal and the bit line signal.

12. The logic device of claim 11, wherein the non-volatile memory cells are arranged in an array.

13. The logic device of claim 11, further comprising:
common source lines connected to source terminals of the plurality of non volatile memory cells.

14. The logic device of claim 11, further comprising:
a decoder configured to generate the word line signal and the bit line signal based on the input signal.

15. The logic device of claim 14, further comprising:
a plurality of separated source lines connected between the plurality of non-volatile memory cells and the decoder,
wherein the plurality of separated source lines are respectively connected to source terminals of non-volatile memory cells disposed in a direction in which the plurality of bit lines extend, from among the plurality of non-volatile memory cells.
